(19) United States
(12) Patent Application Publication
(10) Pub. No.: US 2010/0194423 A1
(43) Pub. Date: Aug. 5, 2010

(54) APPARATUS AND METHOD FOR TESTING SEMICONDUCTOR AND SEMICONDUCTOR DEVICE TO BE TESTED

(76) Inventors: Masamoto Tago, Tokyo (JP); Yoshihiro Nakagawa, Tokyo (JP)

Correspondence Address: Mr. Jackson Chen, 6535 N. STATE HWY 161, IRVING, TX, 75039, US

(21) Appl. No.: 12/679,959

(22) PCT Filed: Sep. 26, 2008
(86) PCT No.: PCT/JP2008/067525

§ 371 Date: Mar. 25, 2010

(30) Foreign Application Priority Data
Sep. 28, 2007 (JP) 2007-255170

(51) Int. Cl. G01R 31/26

(52) U.S. Cl. 324/765

(57) ABSTRACT

Provided is a semiconductor testing apparatus which can perform batch test of semiconductor wafers. In the semiconductor testing apparatus, an LSI apparatus for conducting a test and which provided with a circuit and an electrode for transmitting noncontact signals, and a probe card to which a contact-type probe pin is attached are separately arranged. The semiconductor testing apparatus is provided with a recognition unit for precisely aligning the electrodes of the LSI apparatus for conducting a test, the LSI wafer to be tested and the probe card. The LSI apparatus for conducting a test and a probe pin of the probe card are mounted on a stage or a pressurizing head, and contact can be made to sandwich an LSI wafer to be tested, from both the front surface and the rear surface of the LSI wafer to be tested at the same time.

### TECHNICAL FIELD

The present invention relates to an apparatus and method for testing semiconductor, and more particularly, to an apparatus and method for testing semiconductor which can reduce the number of pins of a contact probe and perform batch test of wafers, and a semiconductor device to be tested.

### BACKGROUND ART

In recent years, there is a rapidly growing demand for higher density semiconductor apparatuses, and high-speed and large volume transmission. Increases in the number of electrode terminals are particularly outstanding and pitch reduction is rapidly advancing for both electrodes arranged in and around an area.

In the above described situation, techniques of testing semiconductor devices having fine pitch electrodes are becoming one key technology. In semiconductor device fabrication in particular, how to conduct test of wafers which is an electric test of devices in a wafer state it is a very important issue. It is possible to improve quality through rapid feedback of problems to a wafer manufacturing step and improve productivity by increasing a production yield rate in volume production of semiconductor devices, and thereby achieve cost reduction.

Test of wafers is roughly divided into a contact scheme and a noncontact scheme in terms of transmitting/receiving signals.

A contact scheme currently used as the mainstream is a scheme whereby some contactor is made to contact a semiconductor device electrode using a probe card as an interface for transmitting/receiving signals between a wafer and a tester.

A contactor used most generally is a probe card called “cantilever scheme” and is a scheme whereby a metal needle is made to contact a semiconductor device electrode. Other examples of the contact scheme used include a membrane sheet with a metal projection (bump), membrane sheet with a TCP (Tape Carrier Package) lead, silicon probe using a plated pin for a silicon whisker and MEMS probe that applies a Si micromachining technique as a probe suitable for batch contact with a wafer.

FIG. 1 illustrates a state of test according to the contact scheme.

Probe card 1001 provided with probe pin 1002 is allowed to move up and down (vertical direction in the figure) through a drive mechanism (not shown). LSI wafer to be tested 1003 provided with electrode 1004 is suctioned by suction hole 1006 provided in stage 1005 and fixed to stage 1005. Probe pin 1002 is connected to an LSI tester (not shown), probe card 1001 descends until probe pin 1002 comes into contact with electrode 1004, and probe pin 1002 supplies power and a signal for test to conduct test of the wafer.

On the other hand, regarding the noncontact scheme, various schemes are disclosed such as a scheme whereby a communication coil is arranged in a semiconductor device and signals are wirelessly inputted/outputted to/from outside devices and a scheme whereby signals are extracted through noncontact capacitative coupling by using a semiconductor device and a mirror-structured chip to cause signal wiring of the semiconductor device to approach wiring of the mirror chip.

Patent Document 1 (U.S. Pat. No. 5,969,533) describes a cantilever scheme using a metal needle, Patent Document 2 (Japanese Patent Laid-Open No. 5-226430) describes a membrane sheet scheme with a metal projection, Patent Document 3 (Japanese Patent Laid-Open No. 6-334006) describes a membrane sheet with a TCP lead, Patent Document 4 (Japanese Patent Laid-Open No. 11-190748) describes a scheme using a silicon whisker, Patent Document 5 (Japanese Patent Laid-Open No. 2003-273180) describes a scheme using a communication coil as a noncontact technique and Patent Document 6 (Japanese Patent Laid-Open No. 2003-344448) describes a scheme extracting signals through capacitative coupling.

FIG. 2 is a diagram illustrating the testing scheme using a communication coil disclosed in Patent Document 5.

FIG. 2(a) is a plan view of wafer 190 and a plurality of semiconductor chips 196 are formed in wafer 190. FIG. 2(b) is an enlarged view of the portion enclosed by a round frame of wafer 190 in FIG. 2(a) where semiconductor chips 196 are provided.

As shown in FIG. 2(b), semiconductor chips 191A and 191B are formed, and communication coils 192A and 192B, and connection terminals 193A and 193B are connected to each other via wires 194A and 194B respectively.

Communication coils 192A and 192B are rectangular spiral coils and are formed on the circuit surface of semiconductor chips 191A and 191B via an insulating surface protective film. Two wires are formed for each communication coil, one wire thereof is connected to a connection terminal inside the semiconductor chip and the other is connected to the connection terminal via a scribe line.

Using the semiconductor chip in the above described structure, test is conducted as shown in FIG. 2(c). ing signal is wirelessly outputted from head 195 of the semiconductor testing apparatus to communication coil 192A of semiconductor chip 191A. Functional test of semiconductor chip 191A is conducted by receiving an output signal from semiconductor chip 191A in response thereto. Test is sequentially conducted on different semiconductor chips by moving this head 195 or each semiconductor chip.

Furthermore, Patent Document 7 (Japanese Patent Laid-Open No. 2004-253561) describes an application to test of wafers. Furthermore, Patent Document 8 (International publication WO2007/029422A1) describes a probe card combining a contact scheme and a noncontact scheme.

Patent Document 1: U.S. Pat. No. 5,969,533

### Patent Document 2: Japanese Patent Laid-Open No. 5-226430

### Patent Document 3: Japanese Patent Laid-Open No. 6-334006

### Patent Document 4: Japanese Patent Laid-Open No. 11-190748

### Patent Document 5: Japanese Patent Laid-Open No. 2003-273180

### Patent Document 6: Japanese Patent Laid-Open No. 2003-344448

### Patent Document 7: Japanese Patent Laid-Open No. 2004-253561

Patent Document 8: International publication WO2007/029422A1

### DISCLOSURE OF THE INVENTION

However, the semiconductor testing apparatus adopting a metal needle or projection contact scheme represented by Patent Document 1 has several problems. First, a probe is configured by laminating four stages of the metal needle and shielding plate from the standpoint of pitch reduction and high-speed signal transmission, and achieving further pitch reduction requires fine machining of the metal needle and a change of material, which makes it very difficult to perform manufacturing and which increases cost.

Furthermore, although the metal needle can be machined, sufficient durability cannot be secured due to insufficient rigidity of the metal needle. Furthermore, since the needle is long, there is a problem in which transmission loss of signals due to resistance increases, thereby producing large signal delays and making it difficult to support high frequencies.

The structure using a membrane sheet disclosed in Patent Document 2 and Patent Document 3 or the like is a structure advantageous for high-speed signal transmission by forming a ground on the rear surface and achieving impedance matching.

However, this is a structure that makes contact with an external electrode of the semiconductor device that uses a metal projection (bump), the metal projection needs to be kept to a certain height or more so as not to contact the circuit surface of the semiconductor device at the time of contacting, and since a manufacturing method using plating is used, it is difficult to make the metal projection adaptable to pitch reduction.

In addition, although the method of using a metal lead that uses a membrane sheet as a probe is likewise advantageous for high-speed signal transmission, the metal lead has a configuration using a film-like flexible material as a base material, and therefore it is difficult to control the positional accuracy in a metal lead pitch direction to a desired value (±1.0 micrometer or less) according to a thermal history of a film substrate manufacturing process.

Furthermore, the probe pin is designed to absorb height variations among elastic metal materials and to obtain a load, and therefore may have difficulty in acquiring good contact characteristics when a material to be contacted changes. Furthermore, since the use of elasticity of the metal material entails deformation of the probe, it is necessary to consider contact due to the deformation or the like of the arrangement of the probe pin, resulting in a problem in which the arrangement density decreases.

Next, problems from the standpoint of contact traces with respect to the electrode of the semiconductor device will be described. There is a mechanism in which after the contactor comes into contact with the electrode, overdrive (amount of rise of the semiconductor device with respect to the contactor relative to the point at which the contactor contacts the electrode=amount of pushing in) is applied as a load and the oxide film of the aluminum electrode surface is thereby broken through in order to achieve contact, whereby contact traces are produced in the aluminum electrode.

The above described contact traces become unstable factors in terms of manufacturing and electric connections in the wire bonding and formation of bumps for flip chip mounting in steps that follow and may result in an open defect, that is, peeling, in the worst case. Furthermore, when pressurization is performed with such a high load that contact traces are formed, if wiring or a circuit of transistors or the like is formed below the aluminum electrode, the wiring or circuit may be destroyed.

Problems of the vertical probe using a silicon whisker illustrated in Patent Document 4 will be described. The vertical probe has a structure in which contact with the electrode is made by a pin which is a plated needle-like single silicon crystal and which has a mechanism in which probing is performed in a direction perpendicular to the electrode of the semiconductor device and in which contact is achieved by making the most of buckling deformation. Thus, contact traces can be kept very small, but since the contact pressure is small, the vertical probe has high contact resistance with respect to the material of the surface oxide film such as aluminum or copper and becomes unstable, making it difficult to achieve good contact with respect to signal pins in particular.

Although growth of the whisker is possible, a conductive metal film needs to be formed on the surface, it is difficult to perform plating onto minute pins, and it is also difficult to secure positional accuracy corresponding to fine pitches due to plating stress and to internal stress or damage in trimming work at a distal end of the probe pin.

Moreover, it is not possible to select a material suitable for most popular aluminum electrodes. Material with a gold-plated film is usually used, but this has a problem with durability. Furthermore, since the pin diameter is extremely small, there is a problem in which when overdrive is applied, the pin may be destroyed because of insufficient pin strength. The technique of forming probes on a wafer collectively using a MEMS technique is also available, but it is necessary to apply metal plating to the surface as in the case of the silicon whisker, which results in a problem with durability and involves high manufacturing cost because the MEMS technique is used.

Next, problems of the noncontact scheme will be described. The inventions disclosed in both Patent Document 5 and Patent Document 6 are of a noncontact-type, and therefore have an advantage in which contact traces on the semiconductor device electrode can be eliminated, but there is a problem with a power supply. Wirelessly supplying power is extremely inefficient in terms of transmission efficiency, transmission of desired power requires formation of a large coil, and an area needs to be secured inside the chip, which increases the chip size and increases cost.

By contrast, the invention described in Patent Document 8 is a probe card combining a contact scheme and a noncontact scheme. Here, sufficient power can be supplied using a probe card which includes a contact-type probe unit for supplying power and an LSI apparatus for conducting a test for carrying out noncontact-type signal transmission through capacitative coupling connected to an intermediate board.

Here, the LSI apparatus for conducting a test and the probe pin of the power supply unit need to be designed so as not to interfere with each other, a region needs to be secured inside the chip and further improvements are expected in terms of the chip size and cost. Furthermore, though the power supply unit and the LSI apparatus for conducting a test are provided with a silicon through-hole electrode and thereby mounted on an intermediate board, there is a problem in which the silicon through-hole electrode requires high cost, yet results in low yield.

Furthermore, the probe card adopts capacitative coupling, though the metal electrode is of a noncontact-type, the distance between electrodes including a dielectric layer needs to be kept uniform. For this reason, parallel high accuracy processing and mounting on the intermediate board is required to appropriately keep the contact position of the probe pin and the contact position of the LSI apparatus for conducting a test. Furthermore, since a testing time needs to be shortened in a testing step, an increase of the number of semiconductor chips simultaneously measured is indispensable, but since a structure is adopted in which the power supply unit and the LSI for test are mounted on the same surface of the intermediate board, it is structurally difficult to test neighboring semiconductor chips and it is difficult to apply the probe card to a wafer batch test.

It is an object of the present invention to provide a semiconductor testing apparatus and a testing method capable of improving the number of semiconductor chips simultaneously measured in a wafer testing step or realizing wafer batch test, and thereby reducing the testing time and improving productivity.

It is another object of the present invention to provide a semiconductor device and testing method applicable to a semiconductor chip with a fine pitch and provided with multiple pin electrodes, and a semiconductor device to be tested.

The semiconductor testing apparatus according to the present invention is a semiconductor testing apparatus that tests an LSI wafer to be tested, including an LSI apparatus for conducting a test provided with an electrode for transmitting a noncontact signal that transmits a signal and power in a noncontact manner to/from the LSI wafer to be tested and a power supply contact-type probe pin or electrode.

The semiconductor device to be tested according to the present invention includes an electrode for transmitting a noncontact signal that transmits a signal or power in a noncontact manner and an electrode for contact that transmits a signal or power through contact.

After aligning the LSI wafer for test with the LSI apparatus for conducting a test, the LSI for test and the LSI to be tested are brought closer to a distance appropriate for noncontact signal transmission and at the same time the probe pin or electrode comes into contact with the power supply electrode of the LSI apparatus for conducting a test and supplies power.

Furthermore, the LSI wafer for test and the probe pin sandwich the LSI apparatus for conducting a test and supply power and a test signal to the LSI apparatus for conducting a test from both sides thereof.

The semiconductor testing method according to the present invention is a semiconductor testing method for testing an LSI wafer to be tested, sandwiching the LSI wafer to be tested by an LSI apparatus for conducting a test provided with an electrode for transmitting a noncontact signal that supplies a signal and power to/from the LSI wafer to be tested in a noncontact manner and provided a probe card having a contact-type probe pin to sandwich the LSI wafer to be tested and supplying power and a test signal to the LSI to be tested from both sides thereof using the LSI apparatus for conducting a test and the probe pin.

### BRIEF DESCRIPTION OF THE DRAWINGS

FIG. 1 is a cross-sectional view illustrating a semiconductor testing apparatus;

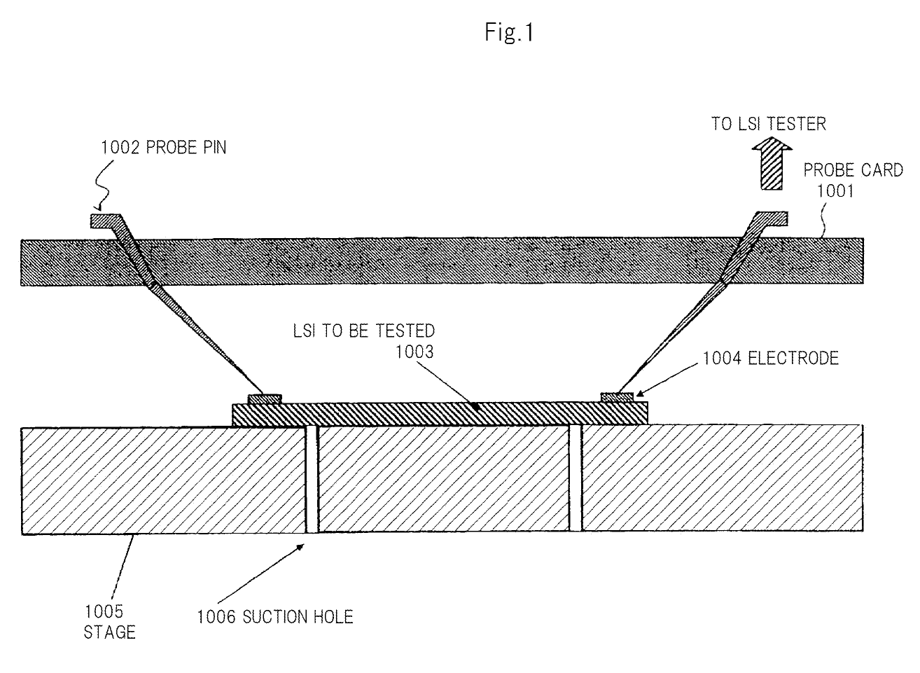

FIG. 2 is a cross-sectional view illustrating the semiconductor testing apparatus;

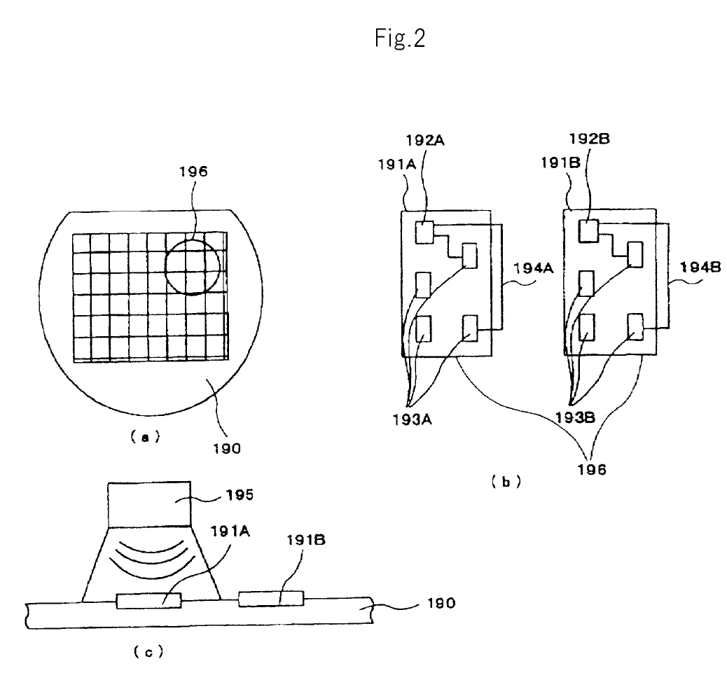

FIG. 3 is a cross-sectional view illustrating a first exemplary embodiment of a semiconductor testing apparatus according to the present invention;

FIG. 4 is a cross-sectional view illustrating a second exemplary embodiment of the semiconductor testing apparatus according to the present invention;

FIG. 5 is a cross-sectional view illustrating a third exemplary embodiment of the semiconductor testing apparatus according to the present invention;

FIG. 6 is a cross-sectional view illustrating a fourth exemplary embodiment of the semiconductor testing apparatus according to the present invention;

FIG. 7 is a cross-sectional view illustrating a fifth exemplary embodiment of the semiconductor testing apparatus according to the present invention;

FIG. 8 is a cross-sectional view illustrating a sixth exemplary embodiment of the semiconductor testing apparatus according to the present invention;

FIG. 9 is a process chart illustrating a process flow from semiconductor test to packaging;

FIG. 10 is a process chart illustrating a process flow from semiconductor test to packaging of the present invention;

FIG. 11 is a cross-sectional view illustrating a first exemplary embodiment of a semiconductor testing method according to the present invention;

FIG. 12 is a cross-sectional view illustrating a configuration of a seventh exemplary embodiment of the present invention; and

FIG. 13(a) is a top view illustrating an arrangement of LSI to be tested 2001 in FIG. 12 and FIG. 13(b) is an enlarged cross-sectional view of main parts thereof.

### DESCRIPTION OF SYMBOLS

101 LSI to be tested (wafer)
102 Electrode for transmitting noncontact signal
103 Electrode for contact
104 Probe card for contact
105 Probe pin
106 LSI for test (wafer)
107 Probe card for transmitting noncontact signal
108 LSI tester
109 Suction hole
110 Suction groove
330 Silicon through-hole electrode
331 Insulating coat
332 Intermediate board
920 Dicing ring
921 Dicing tape

### BEST MODE FOR CARRYING OUT THE INVENTION

Next, exemplary embodiments of the present invention will be described in detail with reference to the accompanying drawings.

In the exemplary embodiments described below, power is supplied to each chip in a wafer using dedicated wiring used only for a power supply at the time of a test. This dedicated wiring is arranged within the wafer in a well-balanced manner to prevent any voltage drop or the like from occurring, and input from outside is connected to a dedicated wiring for a power supply. When the test is completed and the chip is divided into individual pieces, this dedicated wiring for a power supply is cut through dicing. The chip divided into individual pieces is packaged and operated using connections of another power supply wiring provided in the chip beforehand and used at the time of division into individual pieces or wire bonding or the like.

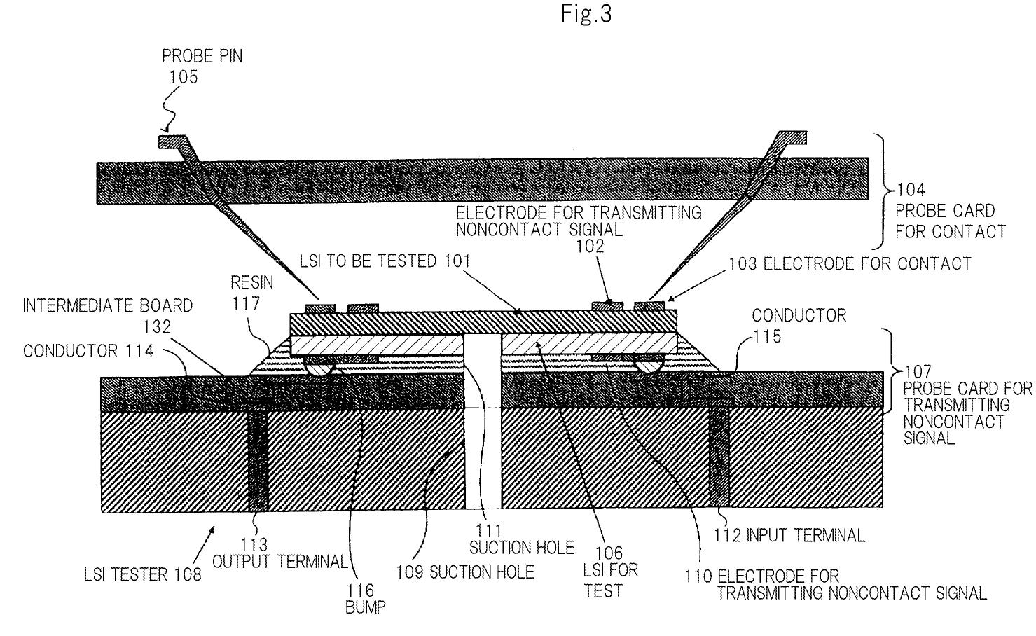

FIG. 3 is a cross-sectional view illustrating a configuration of a first exemplary embodiment of a semiconductor testing apparatus according to the present invention.

The present exemplary embodiment is made up of probe card for contact 104, LSI wafer to be tested 101, probe card for transmitting noncontact signal 107 and LSI tester 108 (stage).

Probe card for contact 104 is provided with probe pin for contact 105.

LSI wafer to be tested 101 is provided with an electrode for contact 103 where the electrode for transmitting noncontact signal 102 contacts probe pin 105.

Probe card for transmitting noncontact signal 107 is a combination of LSI apparatus for conducting a test 106 and intermediate board 132, and LSI apparatus for conducting a test 106 is mounted with a circuit for test of testing LSI wafer to be tested 101. Furthermore, LSI apparatus for conducting a test 106 is provided with an electrode for transmitting noncontact signal 110 that carries out signal transmission to/from the electrode for transmitting noncontact signal 102 of LSI wafer to be tested 101 in a noncontact manner and is further provided with bumps 116 for transmitting a signal of the electrode for transmitting noncontact signal 110 to intermediate board 132. Intermediate board 132 is provided with conductors 114 at locations corresponding to bumps 116. The perimeter of LSI apparatus for conducting a test 106 is sealed with resin 117 and suction hole 111 is formed which penetrates intermediate board 132, resin 117 and LSI apparatus for conducting a test 106.

LSI tester 108 is provided with input terminal 112 and output terminal 113 at locations corresponding to conductors 114 and is provided with suction hole 109 which corresponds to suction hole 111.

LSI for test 106 having a circuit for transmitting a noncontact signal (not shown) and the electrode for transmitting noncontact signal 110 are mounted face down on intermediate board 132 to thereby make up a probe card for transmitting noncontact signal 107 together with intermediate board 132 and are electrically connected to LSI tester 108 via intermediate board 132.

A probe card for transmitting noncontact signal 107 is made to be separate from and independent of probe card for contact 104 to which contact-type probe pin 105 is attached. The probe card for contact 104 is attached to a pressurizing head (not shown) of the testing apparatus and probe pin 105 is connected to a power supply unit (not shown).

A probe card for transmitting noncontact signal 107 is provided with suction hole 111 for suctioning and fixing LSI to be tested 101 at the time of a test and LSI tester 108 is provided with suction hole 109 that communicates with suction hole 111.

A control apparatus (not shown) that controls a positional relationship between LSI to be tested 101 and LSI for test 106 recognizes the positional relationship between the electrode for transmitting noncontact signal 102 of LSI to be tested 101 and the electrode for transmitting noncontact signal 110 of LSI for test 106 corresponding thereto using a camera (not shown) applicable to visible light and a camera (not shown) applicable to infrared rays. Furthermore, the positional relationship is further recognized by a camera (not shown) that recognizes the needle tip of probe pin 105 of probe card for contact 104. Thus, alignment is performed using video images captured by the three cameras and LSI to be tested 101 is suctioned and fixed to probe card for transmitting noncontact signal 107.

The rear surface of LSI to be tested 101 is worked on and thinned by taking into consideration the communication distance within which signals can be transmitted in a noncontact manner.

After the suction and fixing of LSI to be tested 101 is completed, the probe card for contact 104 descends with respect to LSI to be tested 101 through a pressurization mechanism of the testing apparatus and position control, and further probe pin 105 comes into contact with LSI to be tested 101. As a result, LSI for test 106 and probe pin 105 of probe card for contact 104 make contact so as to sandwich the front surface and rear surface of LSI to be tested 101 and an LSI test is started in this condition.

Upon conducting an LSI test, power is supplied to LSI to be tested 101 by probe pin 105, a test signal is generated via input terminal 112 and conductor 115 and a test signal is generated by the circuit for test of LSI to be tested 106 via bumps 116 and supplied to LSI to be tested 101 via electrodes for transmitting noncontact signal 110 and 102. A signal indicating the operation result of LSI to be tested 101 with respect to the test signal is outputted from output terminal 113 via electrodes for transmitting noncontact signal 102 and 110, bumps 116 and conductor 115, and the operation state of LSI to be tested 101 is tested according to the contents thereof.

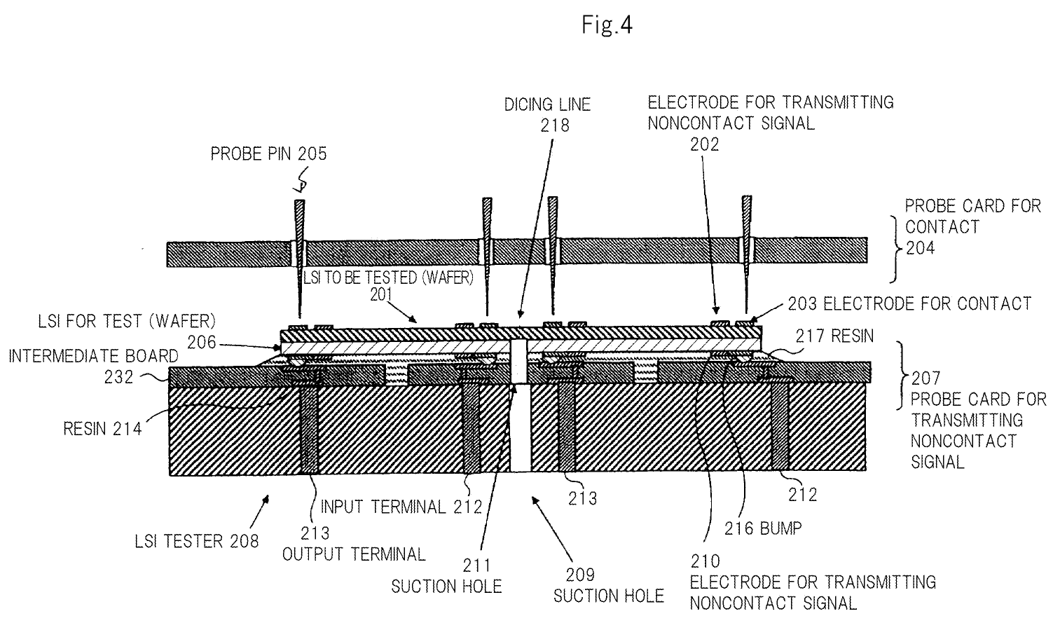

FIG. 4 is a cross-sectional view illustrating a configuration of another exemplary embodiment of the present invention.

The present exemplary embodiment is made up of probe card for contact 204, LSI to be tested 201, probe card for transmitting noncontact signal 207 and LSI tester 208.

Probe card for contact 204 is provided with probe pin for contact 205.

LSI to be tested 201 is provided with an electrode for transmitting noncontact signal 202 and an electrode for contact 203 with which probe pin 205 makes contact.

Probe card for transmitting noncontact signal 207 is a combination of LSI for test 206 and intermediate board 232, and LSI for test 206 is provided with an electrode for transmitting noncontact signal 210 whereby a signal is transmitted to/from the electrode for transmitting noncontact signal 202 of LSI to be tested 201 in a noncontact manner and is also provided with bumps 216 for transmitting a signal of electrode for transmitting noncontact signal 210 to intermediate board 232. Intermediate board 232 is provided with conductors 214 at locations corresponding to bumps 216. The perimeter of LSI for test 206 is sealed with resin 217 and suction hole 211 is formed which penetrates intermediate board 232, resin 217 and LSI for test 206.

LSI tester 208 is provided with input terminal 212 and output terminal 213 at locations corresponding to conductors 214 and is provided with suction hole 209 which corresponds to suction hole 211.

LSI apparatus for conducting a test 206 having a circuit for transmitting noncontact signal (not shown) and the electrode for transmitting noncontact signal 210 are mounted face down on intermediate board 232 to thereby make up probe card for transmitting noncontact signal 207 together with intermediate board 232 and are electrically connected to LSI tester 208 via intermediate board 232.

The probe card for transmitting noncontact signal 207 is made to be separate from and independent of the probe card for contact 204 to which contact-type probe pin 205 is attached. The probe card for contact 204 is attached to a pressurization head (not shown) of the testing apparatus and probe pin 205 is connected to a power supply unit (not shown).

The probe card for transmitting noncontact signal 207 is provided with suction hole 211 for suctioning and fixing LSI wafer to be tested 201 at the time of a test and LSI tester 208 is provided with suction hole 209 that communicates with suction hole 211.

A control apparatus (not shown) that controls the positional relationship between LSI wafer to be tested 1201 and LSI apparatus for conducting a test 1206 recognizes the positional relationship between the electrode for transmitting noncontact signal 202 of LSI wafer to be tested 1201 and the electrode for transmitting noncontact signal 210 of LSI apparatus for conducting a test 1206 corresponding thereto using a camera (not shown) applicable to visible light and a camera (not shown) applicable to infrared rays. Furthermore, the positional relationship is further recognized by a camera (not shown) that recognizes a needle tip of probe pin 205 of probe card for contact 204. Thus, alignment is performed using video images captured by the three cameras and LSI wafer to be tested 1201 is suctioned and fixed to probe card for transmitting noncontact signal 207.

The rear surface of LSI wafer to be tested 201 is worked on and thinned by taking into consideration the communication distance within which signals can be transmitted in a noncontact manner.

After suction and fixing of LSI wafer to be tested 1201 is completed, the probe card for contact 204 descends with respect to LSI apparatus for conducting a test 201 through a pressurization mechanism of the testing apparatus and position control, and further probe pin 205 comes into contact with LSI wafer to be tested 201. As a result, LSI apparatus for conducting a test 1206 and probe pin 205 of probe card for contact 204 make contact so as to sandwich the front surface and rear surface of LSI wafer to be tested 101 and an LSI test is started in this condition.

The present exemplary embodiment configured as described above is intended to test LSI wafer to be tested 201 which corresponds to two LSIs wafer to be tested 101 shown in the exemplary embodiment in FIG. 3 coupled together. LSI apparatus for conducting a test 206 has a configuration which corresponds to two LSIs apparatus for conducting a test 106 shown in FIG. 3 in correspondence with LSI wafer to be tested 201, coupled together, and LSI wafer to be tested 201 after the test is cut along dicing line 218.

A testing step is usually performed in a wafer state and in particular, especially the greater the number of semiconductor chips to be measured simultaneously, the higher is the test efficiency and the shorter is the time required, and the cost is thereby reduced. The configuration shown in the present exemplary embodiment represents the configuration for testing a plurality of wafers or for performing batch test on the front surfaces of wafers.

A vertical-type probe pin is used as probe pin 205 of probe card for contact 204 as shown in the figure. This makes it possible to increase the number of semiconductor chips to be measured simultaneously. Compared to the contact from a diagonal direction shown in FIG. 3, vertical-type probe pin 205 may have higher contact resistance or may have deeper contact traces. However, since the vertical-type probe pin is applied to only a power supply here, it is not necessary to give a lot of consideration to the magnitude and variation of contact resistance so much and even if there is an unstable state due to wire bonding or the like in the next step, a redundant function in which a plurality of power supplies themselves are connected in parallel will not lead to any failure.

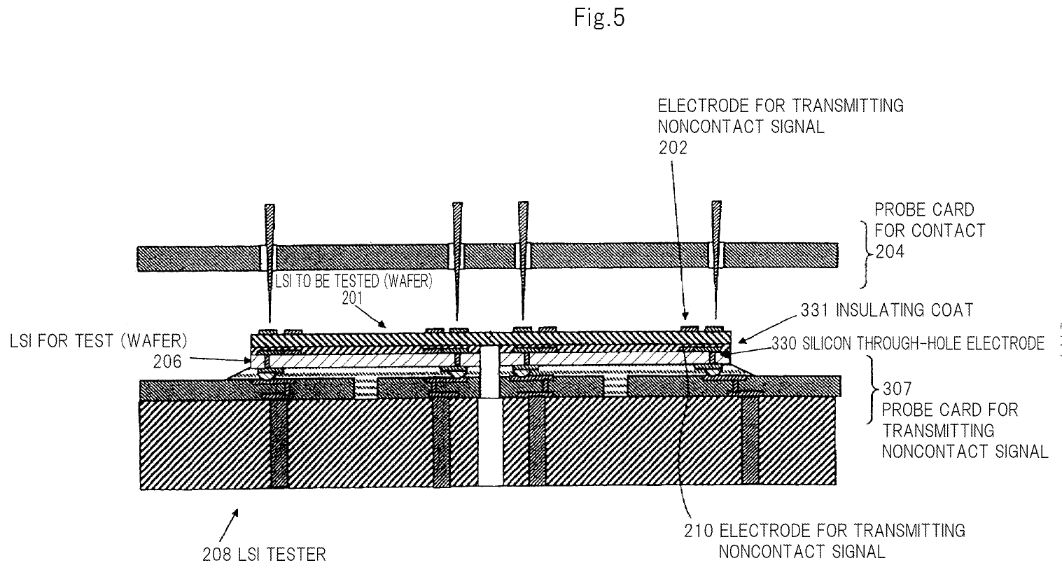

FIG. 5 is a cross-sectional view illustrating a configuration of a third exemplary embodiment of the present invention.

The present exemplary embodiment replaces probe card for transmitting noncontact signal 207 according to the second exemplary embodiment shown in FIG. 4 by probe card for transmitting noncontact signal 307 provided with silicon through-hole electrode 330 and insulating coat 331. The rest of the configuration is similar to that of the exemplary embodiment shown in FIG. 4.

When LSI wafer to be tested 201 is tested without reducing the thickness thereof and in consideration of the case where it is difficult to carry out noncontact signal transmission, the present exemplary embodiment shortens the distance between the electrode for transmitting noncontact signal 202 of LSI wafer to be tested 201 and the electrode for transmitting noncontact signal 220 of LSI apparatus for conducting a test 206, and therefore silicon through-hole electrode 330 is formed in LSI apparatus for conducting a test 306 and mounted face up. In this case, in consideration of the unevenness of the surface of LSI apparatus for conducting a test 306 caused by the electrode for transmitting noncontact signal 202, wiring or the like, insulating coat 31 is applied which does not cause the suction stage function to deteriorate and which also allows the surface to be protected and the surface is flattened.

When LSI apparatus for conducting a test 206 shown in FIG. 4 is mounted face down, above insulating coat 331 may also be applied for the purpose of protecting the surface. Applying insulating coat 331 drastically improves durability.

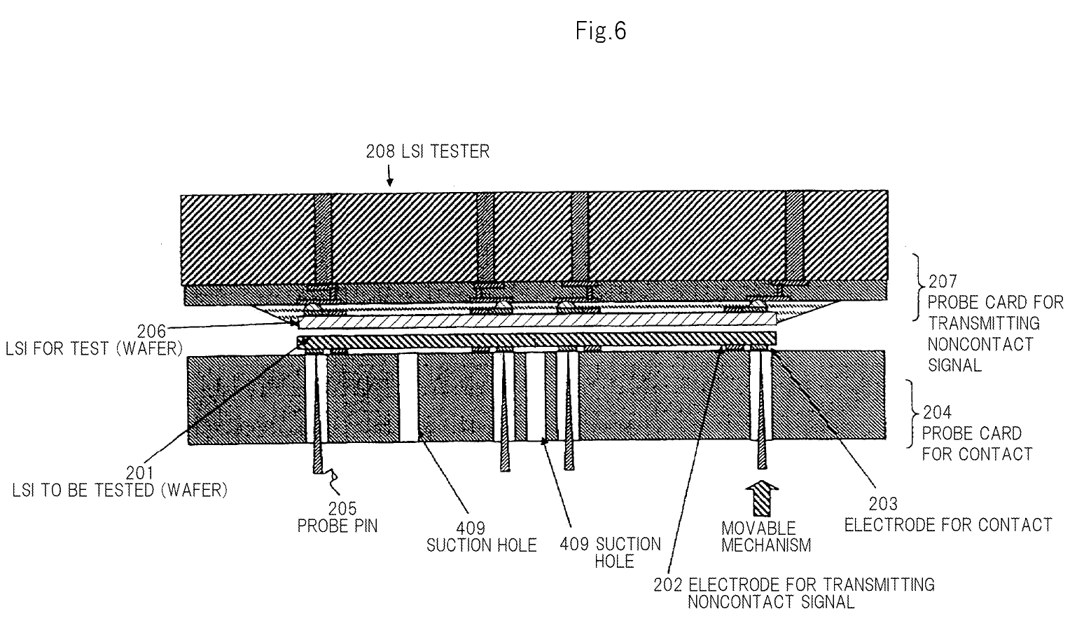

FIG. 6 is a cross-sectional view illustrating a configuration of a fourth exemplary embodiment of the present invention.

The present exemplary embodiment attaches LSI tester 208 according to the second exemplary embodiment shown in FIG. 4 to a pressurizing head (not shown) of the testing apparatus and connects probe card for contact 204 to a power supply unit (not shown). Therefore, suction hole 209 and suction hole 211 provided for probe card for transmitting noncontact signal 207 and LSI tester 208 are not provided here and probe card for contact 204 is provided with suction hole 409 instead.

According to the apparatus configuration of the present exemplary embodiment, the configuration can be changed as appropriate according to environments of the existing probe card or tester. However, when probe card for contact 204 is arranged on the stage (power supply unit) side, probe pin 205 usually does not protrude from the card surface, and it is preferable to adopt a two-stage drive mechanism such that LSI wafer to be tested 201 is suctioned first and then contacted or a structure provided with a plate or the like in which a guide hole is formed aligned with the position of probe pin 205.

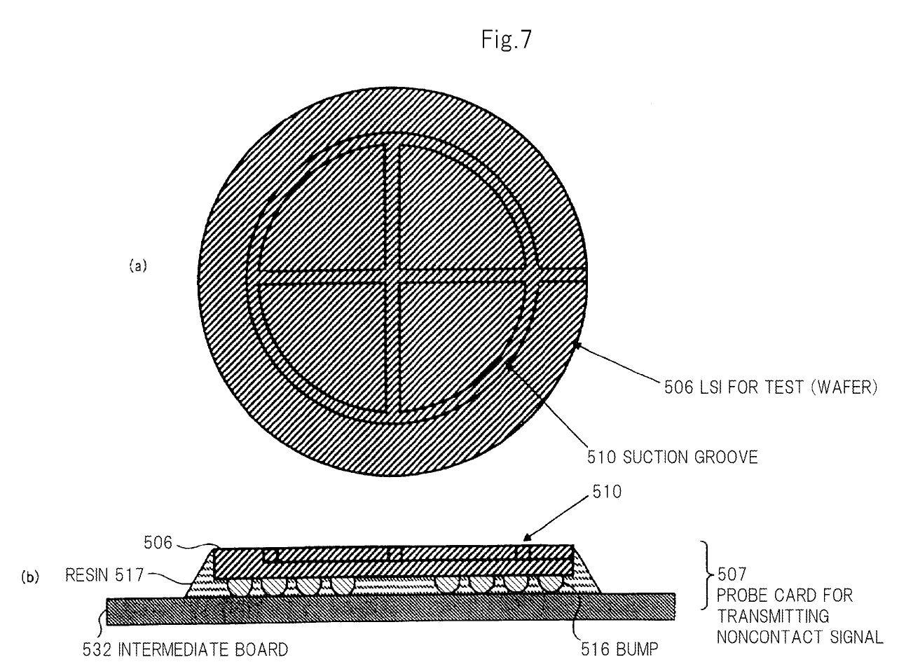

FIG. 7 is a diagram illustrating a configuration of main parts of a fifth exemplary embodiment of the present invention.

The present exemplary embodiment provides a suction mechanism for an LSI apparatus for conducting a test itself that makes up a probe card for transmitting a noncontact signal. FIG. 7(a) is a top view of LSI for test 506 and FIG. 7(b) is a cross-sectional view illustrating a structure of probe card for transmitting noncontact signal 507.

Suction groove 510 for causing LSI apparatus for conducting a test 506 to function have a suction stage function at suction stage is formed in LSI apparatus for conducting a test 506. Suction groove 510 is a groove formed using a technique such as etching whereby an LSI wafer to be tested (not shown) is aligned, mounted and then the end of suction groove 510 is clamped so as not to leak and suctioned using a vacuum pump.

Bumps 516, resin 517 and intermediate board 532 in FIG. 7(b) are similar to bumps 216, resin 217 and intermediate board 232 shown in FIG. 4, but since LSI apparatus for conducting a test 506 itself is provided with a suction mechanism in the present exemplary embodiment, suction hole 211 in FIG. 4 is unnecessary and a circuit for test can be mounted on LSI apparatus for conducting a test 506 using the space corresponding thereto. According to the structure of the present exemplary embodiment, it is possible to obtain a suction function by only working on the surface of LSI for test 506, mount more circuits for test and thereby have a high test function.

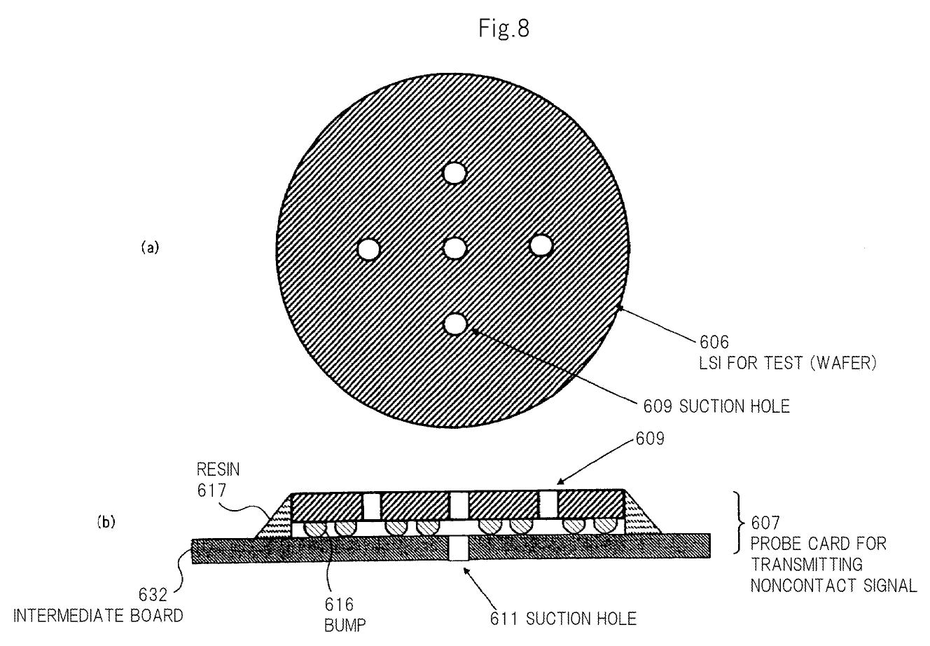

FIG. 8 is a diagram illustrating a configuration of main parts of a sixth exemplary embodiment of the present invention.

The present exemplary embodiment illustrates another suction mechanism of a probe card for transmitting a noncontact signal. FIG. 8(a) is a top view of LSI for test 606 and FIG. 8(b) is a cross-sectional view illustrating a structure of a probe card for transmitting noncontact signal 607.

The present exemplary embodiment forms a plurality of penetrating suction holes 609 in LSI apparatus for conducting a test 606, mounts LSI apparatus for conducting a test 606 on intermediate board 632, then seals the perimeter of LSI for test 606 with resin 617. Intermediate board 632 is provided with suction hole 611 and vacuum suction using suction holes 609 that communicate with suction hole 611 is performed by evacuating suction hole 611.

The exemplary embodiments so far have shown the method of fixing an LSI wafer to be tested by means of vacuum suction, but a method using an electrostatic chuck or mechanical clamp scheme that guides the perimeter of a wafer may also be adopted.

Next, a seventh exemplary embodiment of the present invention will be described.

When a noncontact transmission as described in the present invention is carried out, the thickness of the wafer needs to be sufficiently small to carry out efficient transmission. This means that the mechanical strength of the wafer deteriorates and damage may occur when the wafer is transferred before and after a test. The present exemplary embodiment is a technique for preventing such damage and is intended to reinforce the strength by thinning the wafer and then pasting a dicing sheet.

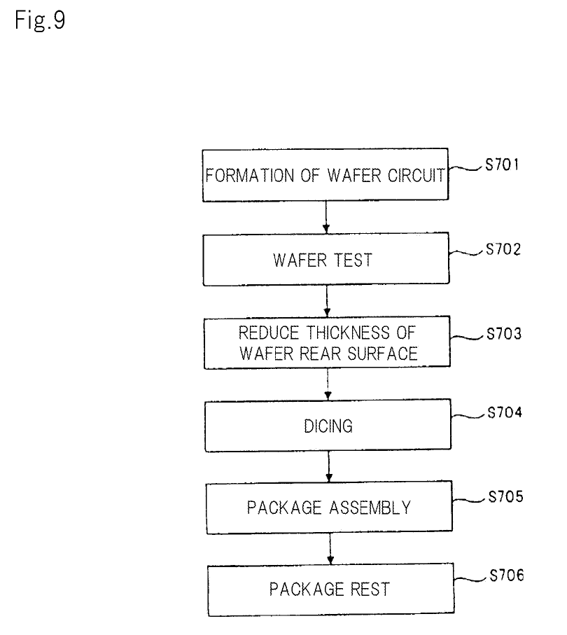

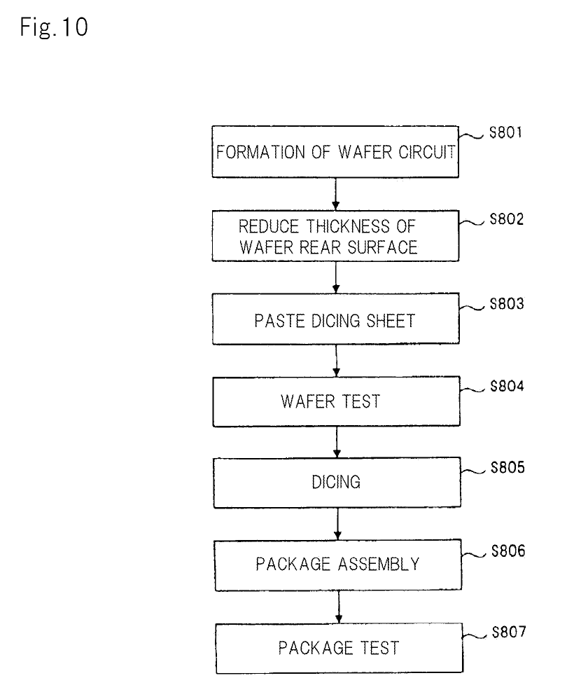

FIG. 9 is a flowchart illustrating general steps up to package assembly as a comparative example and FIG. 10 is a flowchart illustrating steps up to package assembly according to the present exemplary embodiment.

A circuit is formed in the wafer (step S701), the wafer is tested through a wafer test (step S702), the rear surface of the wafer is thinned (step S703) and then dicing is performed (step S704). The package is then assembled (step S705) and subjected to a package test (step S706).

By contrast, according to the present exemplary embodiment, as shown in FIG. 10, after a circuit is formed in the wafer (step S801), the circuit surface of the wafer is protected by tape and the rear surface is thinned (step S802).

Next, the circuit surface of the wafer is then transferred to another tape to peel the protective tape, and in this case, a dicing sheet is pasted using a tape and a ring used for dicing (step S803) so that the thinned wafer may be handled easily. In this condition, a wafer test is conducted using a semiconductor testing apparatus according to the exemplary embodiment shown in FIG. 3 to FIG. 8 (step S804). Next, a dicing step, which is a package assembly step, is performed (step S805), and the wafer can be transferred in the same mode as in step S804. After that, the package is assembled (step S806) and a package test is conducted (step S807).

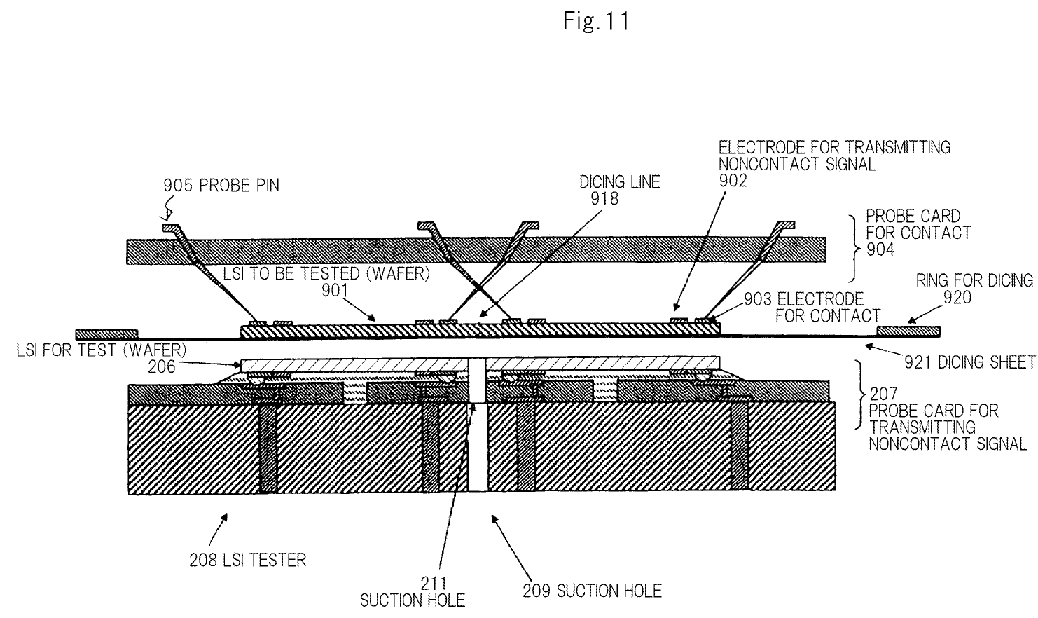

FIG. 11 is a diagram illustrating a test state of the present exemplary embodiment.

In the configuration shown in FIG. 11, LSI apparatus for conducting a test 206, probe card for transmitting noncontact signal 207 and LSI tester 208 are the same as those shown in FIG. 4. The present exemplary embodiment is configured so that probe pin 905 making up probe card for contact 904 is diagonally disposed so as to contact electrode for contact 903 of LSI wafer to be tested 901. LSI wafer to be tested 901 is pasted to dicing sheet 921 together with dicing ring 920 and subjected to a wafer test in that condition.

Working on the LSI wafer to be tested to reduce the thickness thereof can suppress damage in the test step due to warpage of the wafer and a reduction of mechanical strength to a minimum and can shorten the communication distance.

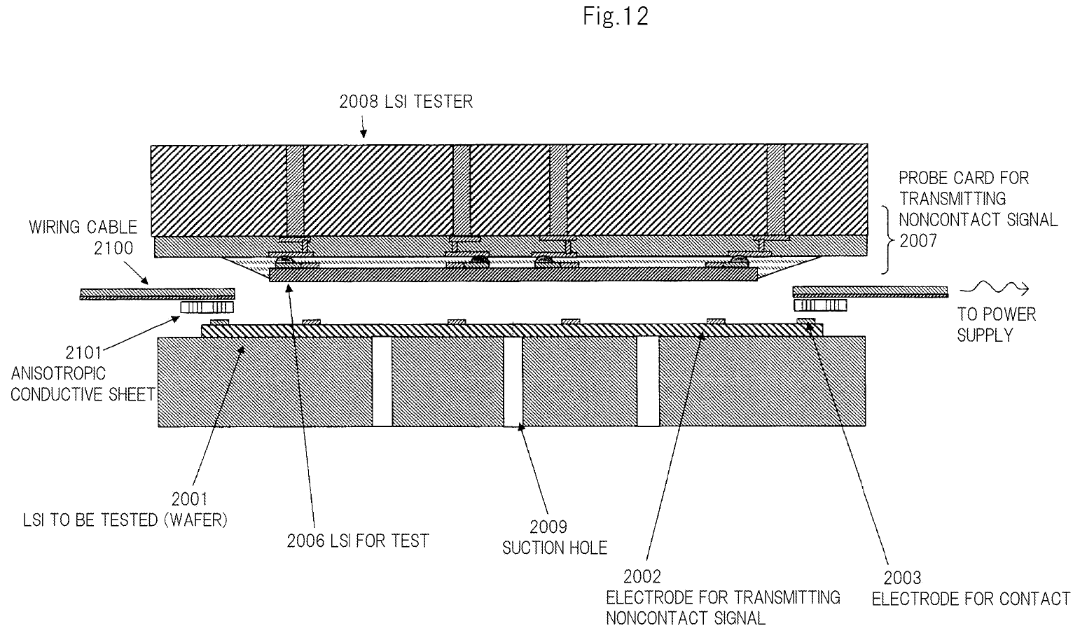

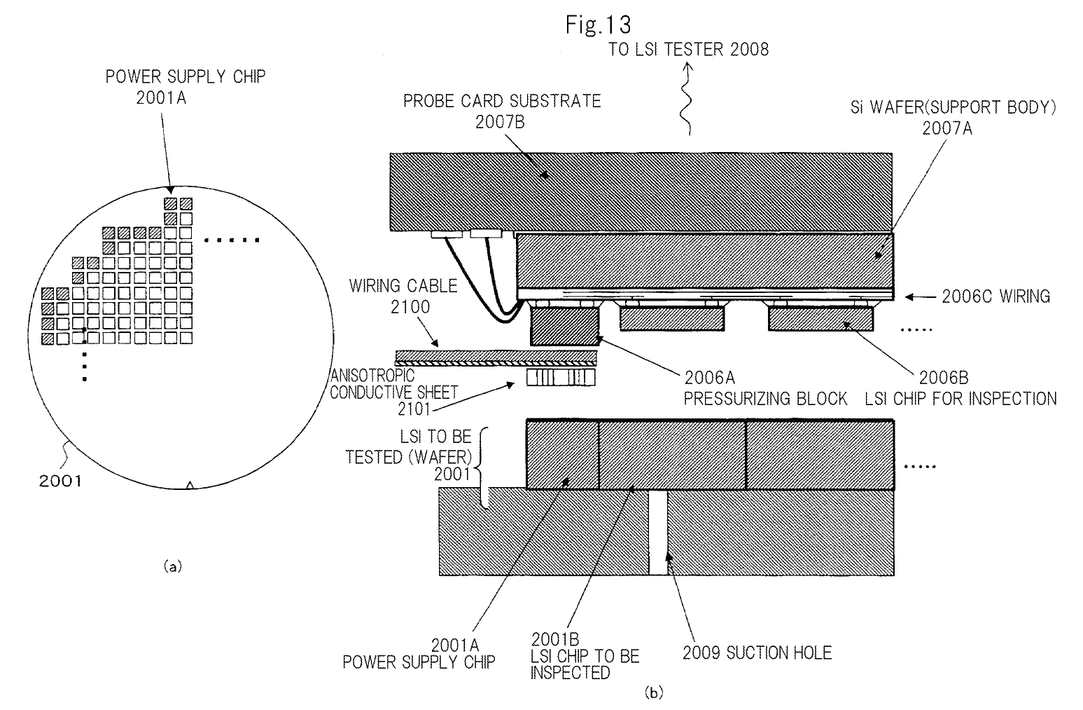

FIG. 12 is a cross-sectional view illustrating a configuration of a seventh exemplary embodiment of the present invention, FIG. 13(a) is a top view illustrating an arrangement of LSI wafer to be tested 2001 in FIG. 12 and FIG. 13(b) is an enlarged cross-sectional view of main parts thereof.

Hereinafter, the structure thereof will be described with reference to FIG. 12 and FIG. 13.

The present exemplary embodiment forms wiring 2006C in Si wafer 2007A, which is a support body, mounts LSI chip for test 2006B aligned with a product wafer in the same array pitch to serve as probe card for transmitting noncontact signal 2007. The probe card for transmitting noncontact signal 2007 is mounted on probe card substrate 2007B and connected to LSI tester 2008.

The electrode for transmitting noncontact signal 2002, the electrode for contact 2003 and suction hole 2009 operate in the same way as the electrode for transmitting noncontact signal 110, the electrode for contact 103 and suction hole 111 shown in FIG. 3.

LSI wafer to be tested 2001, which is a wafer, is provided with power supply chip 2001A provided with a power supply pad on the perimeter as shown in FIG. 13(a). The power supply line of LSI chip to be tested 2001B is shared as a common line in LSI wafer to be tested 2001.

When probe card for transmitting noncontact signal 2007 descends to the position where noncontact test is performed while carrying out alignment, wiring cable 2100 is pressurized by pressurizing block 2006A mounted on probe card for transmitting noncontact signal 2007, pressed by power supply chip 2001A via anisotropic conductive resin sheet 2101 and an electric connection is thereby obtained.

Pressurizing block 2006A can control the distance between LSI apparatus for conducting a test 2006 and LSI wafer to be tested 2001 at the time of pressurization according to the thickness and mounting height thereof.

Furthermore, as other means, it is also possible to mount power supply wiring on the probe card for transmitting noncontact signal and to pressurize the anisotropic conductive sheet through this wiring. When such a configuration is adopted, it is possible to control the distance between the LSI apparatus for conducting a test and the LSI wafer to be tested at the time of pressurization by adjusting the mounting height of wiring beforehand.

One of the features of the present exemplary embodiment is that when part of the power supply wiring is connected to the LSI apparatus for conducting a test, the present invention is also applicable to a power supply to the LSI apparatus for conducting a test and signal transmission. Conventionally, a multilayered and expensive substrate is used for the probe card substrate, but if the LSI apparatus for conducting a test is provided with a test judgment function conventionally performed using a tester and if only a testing result can be extracted as in the case of the present exemplary embodiment, it is possible to extremely reduce the number of leads necessary for signal transmission and realize a drastic cost reduction by applying the wiring cable to driving the LSI apparatus for conducting a test and transmission of the testing result.

Another feature of the present exemplary embodiment is that providing a dedicated electrode for a power supply to supply power to specific locations of the LSI wafer to be tested can solve the conventional problem in which it is difficult to use an anisotropic conductive sheet. Conventionally, when a configuration using an anisotropic conductive sheet inserted is adopted, there is a possibility that the conductive sheet may be insulated by the influence of siloxane contained in silicon-based resin used for the sheet, and therefore the sheet is arranged so that it does not make direct contact, but is arranged to make contact via a metal projection such as a membrane sheet. According to the present exemplary embodiment, the power supply chip provided on the product wafer is not shipped as a product and the power supply chip will no longer be used from the next step onward, and therefore there is no problem and the present exemplary embodiment provides a structure having low cost and that is appropriate for extremely small space that is suitable for noncontact test.

A case has been described in the above exemplary embodiments where power is supplied to an LSI wafer to be tested via the probe pin and a test signal is supplied via the LSI apparatus for conducting a test, but the present invention is not limited to this. One or both of the test signal and power supply may be supplied to the probe pin and LSI apparatus for conducting a test. What is important in the present invention is that spatial restrictions on a semiconductor chip made to have a finer pitch and many pin electrodes can be relaxed by supplying power and electric signals from both sides of the LSI wafer to be tested, and power that needs to be supplied for test of the LSI wafer to be tested and the type of test signal may be supplied from any one of the sides.

Furthermore, the electrode used to supply power to the LSI wafer to be tested may be distinguished from the product LSI and formed for test-specific purpose. Although the number of LSI chips produced per wafer may decrease, there is an advantage in which contact traces due to a power supply or contamination that occurs at the time of contact are not introduced into the product.

The semiconductor testing apparatus configured as described above includes an LSI apparatus for conducting a test having a circuit and an electrode for transmitting a noncontact signal and a probe card provided with a contact-type probe pin, arranged separately from and independently of each other, and can thereby reduce the pitch of the probe pin. Contact for a power supply can be made via the probe pin, and the probe is exclusively attached to only an electrode pin necessary for test and a noncontact signal transmission is used for the electrode pin used for signal transmission to thereby manufacture the apparatus in the same process as in the step for manufacturing a semiconductor chip, which facilitates miniaturization. This relaxes the fine pitch, which has been the problem in manufacturing the contact probe and noncontact probe disposed independently of each other, thereby increases the space for mounting the contact probe, thereby allows more probes to be installed than in the related art, making it possible to increase the number of semiconductor chips to be measured simultaneously during a test in a wafer state and improving production efficiency in the testing step.

For this purpose, a configuration is provided such that an LSI apparatus for conducting a test is mounted aligned with the same position as an LSI wafer to be tested, a power supply electrode is provided for the LSI wafer to be tested, a probe or electrode that makes contact is provided for pressurization and at the same time the LSI apparatus for conducting a test having a noncontact signal transmission function and the LSI wafer to be tested can be located at a distance within which signals can be transmitted.

Furthermore, the apparatus that makes contact with the LSI wafer to be tested from up and down causes the LSI apparatus for conducting a test that, in particular, has a noncontact signal transmission function, to be mounted face down on the testing apparatus, and the rear surface of the LSI apparatus for conducting a test is worked on so as to suction and hold the LSI to be tested to thereby function as a stage. Furthermore, suppose a configuration is provided such that a recognition unit for precisely aligning the electrodes of the LSI apparatus for conducting a test, the LSI wafer to be tested and the probe card is provided, LSI apparatus for conducting a test and the probe pin of the probe card will be mounted on the stage or pressurizing head so that contact can be made in such a way as to sandwich the LSI wafer to be tested from the front and rear surfaces of the LSI wafer to be tested simultaneously.

Furthermore, since making a communication distance as short as possible in noncontact signal transmission is advantageous from the standpoint of power saving, pitch reduction or interference with neighboring electrodes or the like, a silicon through-hole electrode is formed in the LSI apparatus for conducting a test and can be mounted face up. In this case, when the LSI apparatus for conducting a test as the stage, the wiring efficiency of the circuit surface subjected to groove working decreases, and therefore a plurality of suction holes are provided.

Likewise, the rear surface of the LSI wafer to be tested may be ground and the wafer itself may be thinned to decrease the communication distance to thereby improve efficiency of noncontact-type signal transmission. In this case, the prior art adopts a step of working on the LSI wafer to a desired thickness and assembling a package after test, but when the wafer is thinned in the wafer testing step, the wafer may bend or the strength may be weakened and the LSI wafer may be broken in the testing step. For this reason, after the step of grinding the rear surface of the LSI wafer to be tested, a step of pasting a semiconductor wafer to a dicing sheet to cut the semiconductor wafer into individual pieces and attaching a ring is executed, the semiconductor wafer pasted to the dicing sheet is aligned with the testing LSI, and using a testing method for testing the wafer by a pressurizing head mounted with a probe card causing the probe pin to contact the LSI wafer to be tested through weight control, and position control makes it possible to realize a thickness reduction for the test step and a thickness reduction for mounting at a time, thereby improving production efficiency, reducing cost and further protecting the wafer by pasting the wafer to the dicing sheet and improving reliability.

Furthermore, by limiting the contact to the power supply pin, it is possible to limit the contact to the minimum necessary contact and to suppress defects in the subsequent assembly step such as wire bonding caused by contact traces to a minimum.

Furthermore, the probe card for transmitting noncontact signal is mounted with an LSI wafer for test and provided with grooves for suction or holes for suction, and can thereby provide a semiconductor testing apparatus that realizes high accuracy flatness.

Furthermore, when the rear surface of the LSI wafer for test is thinned through grinding or the like to improve the signal transmission characteristic of noncontact signal transmission, it is possible to provide a testing method capable of protecting the wafer so as to prevent defects such as breakage of the wafer even if a test is performed after a thickness reduction down to a thickness applicable to a final product.

As a specific technique applied to noncontact signal transmission according to the present invention, electromagnetic induction through an inductor is applied. According to noncontact signal transmission using an inductor, signal transmission is possible even if there is no inductor on the outermost surface of the LSI wafer to be tested, and there is an advantage that the LSI can be arranged without deteriorating the degree of freedom in design of the LSI such as below or in the middle of the wiring or electrode or the like. When the electrode for transmitting noncontact signal is arranged on the outermost surface of the LSI wafer to be tested, capacitative coupling using a capacitor can also be applied.

The electrode for transmitting noncontact signal according to the aforementioned exemplary embodiments is formed parallel to the electrode for contact for performing wire bonding or flip chip bonding (including the electrode for contact for probe contact depending on circumstances). Although connected in parallel, if both the electrode for transmitting a noncontact signal and the electrode for contact function simultaneously, operation defects may be produced at the time of LSI wafer test and package assembly (when finished as a product), and therefore a selector circuit (function) is provided between the electrode for transmitting a noncontact signal and the electrode for contact so that both electrodes operate separately from and independently of each other.

Furthermore, although a mode has been illustrated where the electrode for transmitting a noncontact signal and the electrode for contact are next to each other, it is also possible to insert an insulating layer beneath the electrode for contact and form the electrode for transmitting a noncontact signal.

Moreover, the electrode for transmitting a noncontact signal and the circuit for transmission/reception may not necessarily be provided inside the LSI wafer to be tested, that is, the electrode for transmitting a noncontact signal and the circuit for transmission/reception need only to function when a wafer test is conducted, and therefore the electrode for transmitting a noncontact signal and the circuit for transmission/reception can be arranged on a scribe line provided beforehand to cut the LSI into individual pieces.

Furthermore, from the standpoint of effectively using the scribe line, an electrode for contact to supply power can be disposed on the scribe line. As an effect thereof, it is possible to increase the area and wiring density when the power line needs to be enhanced.

Furthermore, although a case has been described where the electrode for transmitting noncontact signal is also provided for the LSI wafer to be tested, a configuration whereby the electrode for transmitting a noncontact signal is provided only on the side of the LSI apparatus for conducting a test. This is because even a normal electrode can carry out noncontact signal transmission depending on conditions and in such a case, the electrode for transmitting a noncontact signal need not be provided for the LSI wafer to be tested.

By separating a noncontact signal transmission probe contact from a contact-type probe contact and simultaneously conducting LSI tests from the front and rear surfaces of the LSI wafer to be tested, it is possible to realize miniaturization and multi-pin implementation of the probe and electrode, realize a low cost probe card, and thereby provide a semiconductor testing apparatus capable of drastically improving the number of semiconductor chips to be measured simultaneously in the testing step, reducing the time required for testing steps and realizing cost reduction.

The invention of the present application has been described so far with reference to the exemplary embodiments, but the invention of the present application is not limited to the above described exemplary embodiments. As in the case of an example shown in the first exemplary embodiment, various modifications that can be understood by those skilled in the art can be made to the configuration and details of the invention of the present application within the scope of the invention of the present application.

The present application claims priority based on Japanese Patent Application No. 2007-255170 filed on Sep. 28, 2007, the disclosure of which is incorporated herein by reference in its entirety.

1. A semiconductor testing apparatus that tests an LSI wafer to be tested, comprising:
an LSI apparatus for conducting a test comprising an electrode for transmitting a noncontact signal that supplies a signal and power in a noncontact manner to/from the LSI wafer to be tested; and
a contact-type probe pin or electrode,
wherein power and a test signal are supplied by the LSI apparatus for conducting a test and the probe pin or the electrode.

2. The semiconductor testing apparatus according to claim 1, wherein the contact-type electrode is made of an anisotropic conductive material and has a structure whereby pressurization is possible by a pressurizing block attached to a probe card on which the LSI apparatus for conducting a test is mounted via wiring.

3. The semiconductor testing apparatus according to claim 1, wherein a structure is adopted whereby the wiring is mounted on a probe card and the wiring allows pressurization via the anisotropic conductive material.

4. A semiconductor testing apparatus that tests an LSI wafer to be tested, comprising:
an LSI apparatus for conducting a test comprising an electrode for transmitting a noncontact signal that supplies a signal and power in a noncontact manner to/from the LSI wafer to be tested; and
a probe card comprising a contact-type probe pin,
wherein the LSI wafer to be tested is sandwiched by the LSI apparatus for conducting a test and the probe pin, and power and a test signal are supplied to the LSI wafer to be tested from both sides thereof by the LSI apparatus for conducting a test and the probe pin.

5. The semiconductor testing apparatus according to claim 4, wherein either of the LSI apparatus for conducting a test or the probe pin is mounted on a stage, the other is attached to a pressurizing head opposed to the stage configured so as to be able to adjust a distance from the stage, and the LSI wafer to be tested is sandwiched between the LSI apparatus for conducting a test and the probe pin when the pressurizing head moves.

6. The semiconductor testing apparatus according to claim 5, wherein the LSI apparatus for conducting a test is mounted face down on the stage and has a function of securing the LSI wafer to be tested.

7. The semiconductor testing apparatus according to claim 5, wherein a silicon through-hole electrode is formed in the LSI apparatus for conducting a test, mounted face up on the stage and has a function of securing the LSI wafer to be tested.

8. The semiconductor testing apparatus according to claim 4, wherein the probe pin makes contact with a pin used to supply power to the LSI wafer to be tested.

9. A semiconductor device to be tested comprising:
an electrode for transmitting a noncontact signal that supplies a signal or power in a noncontact manner; and
an electrode for contact that transmits a signal and power through contact.

10. A semiconductor device to be tested comprising:
a semiconductor device used as an actual product; and
a power supply semiconductor device whose power supply is shared with said semiconductor device, provided to supply power to the outside.

11. A semiconductor testing method for testing an LSI wafer to be tested, comprising:
sandwiching the LSI wafer to be tested by an LSI apparatus for conducting a test comprising an electrode for transmitting a noncontact signal that supplies a signal and power to/from the LSI wafer to be tested in a noncontact manner and a probe card comprising a contact-type probe pin; and
supplying power and a test signal to the LSI wafer to be tested from both sides thereof by the LSI apparatus for conducting a test and the probe pin.

12. The semiconductor testing apparatus according to claim 5, wherein the probe pin makes contact with a pin used to supply power to the LSI wafer to be tested.

13. The semiconductor testing apparatus according to claim 6, wherein the probe pin makes contact with a pin used to supply power to the LSI wafer to be tested.

14. The semiconductor testing apparatus according to claim 7, wherein the probe pin makes contact with a pin used to supply power to the LSI wafer to be tested.
